(19) United States
(12) Patent Application Publication
(10) Pub. No.: US 2024/0274578 A1
(43) Pub. Date: Aug. 15, 2024

(54) STACKED SEMICONDUCTOR DEVICE

(71) Applicant: Micron Technology, Inc., Boise, ID (US)

(72) Inventor: Jong Sik Paek, Taichung (TW)

(21) Appl. No.: 18/407,428

(22) Filed: Jan. 8, 2024

Related U.S. Application Data
(60) Provisional application No. 63/444,345, filed on Feb. 9, 2023.

(51) Int. Cl. H01L 25/065; H01L 21/48; H01L 23/00; H01L 23/498; H10B 80/00

(52) U.S. Cl. CPC H01L 25/0657; H01L 21/4853; H01L 23/49838; H01L 23/49894; H01L 24/16; H01L 24/32; H01L 24/48; H01L 24/73; H01L 25/0652; H10B 80/00; H01L 2224/16227; H01L 2224/32225; H01L 2224/48105; H01L 2224/48145; H01L 2224/48227; H01L 2224/73204; H01L 2224/73257; H01L 2224/73265; H01L 2225/06506; H01L 2225/0651; H01L 2225/06517; H01L 2225/06562; H01L 2924/1431; H01L 2924/1436; H01L 2924/1438

(57) ABSTRACT

A semiconductor device assembly is provided. The semiconductor device assembly includes a first semiconductor die electrically coupled with a redistribution layer through first conductive structures. A stack of semiconductor dies is mounted on the first semiconductor die and electrically coupled with the redistribution layer. For example, a base die of the stack of semiconductor dies is mounted on the first semiconductor die, and second conductive structures electrically couple the base die with the redistribution layer. The semiconductor dies in the stack of semiconductor dies are electrically coupled through one or more wires. In doing so, a compact and reliable semiconductor device may be assembled.

### CROSS-REFERENCE TO RELATED APPLICATION(S)

The present application claims priority to U.S. Provisional Patent Application No. 63/444,345, filed Feb. 9, 2023, the disclosure of which is incorporated herein by reference in its entirety.

### TECHNICAL FIELD

The present disclosure generally relates to semiconductor device assemblies and more particularly relates to a stacked semiconductor device.

### TECHNICAL FIELD

The present disclosure generally relates to semiconductor device assemblies and more particularly relates to a stacked semiconductor device.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly.

FIG. 2 illustrates a simplified schematic cross-sectional view of a semiconductor device assembly in accordance with an embodiment of the present technology.

FIGS. 3-11 illustrate simplified schematic plan and cross-sectional views of a series of steps for fabricating semiconductor device assemblies in accordance with an embodiment of the present technology.

FIG. 12 illustrates a simplified schematic cross-sectional view of a semiconductor device assembly in accordance with an embodiment of the present technology.

FIG. 13 illustrates a schematic view of a system that includes a semiconductor device assembly configured in accordance with an embodiment of the present technology.

FIG. 14 illustrates a method of making a semiconductor device assembly in accordance with an embodiment of the present technology.

### DETAILED DESCRIPTION

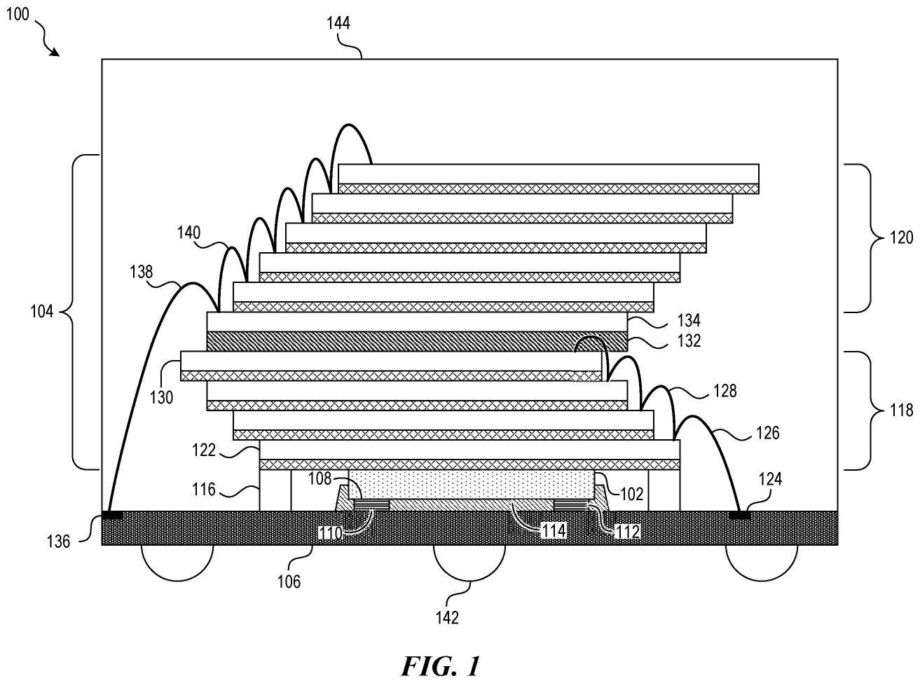

Packaged semiconductor devices enable multiple circuit components within a single package. Different packaged semiconductor devices may be designed to meet different specifications based on the application of the device. For example, a packaged semiconductor device may be constrained in size (e.g., footprint, height, etc.) based on the size of the electronic device in which it is implemented. In other examples, a packaged semiconductor device may be required to have certain thermal properties. Moreover, some packaged semiconductor device designs may be fabricated through techniques that produce inconsistencies in the devices, which can impede circuitry within the devices from performing as intended. Thus, some packaged semiconductor device designs may be suboptimal for certain applications. One such design is shown by way of example in FIG. 1.

FIG. 1 illustrates a semiconductor device assembly 100 that includes a logic die 102 (e.g., controller) and a stack of memory dies 104 (e.g., dynamic random-access memory (DRAM) dies, NOT-AND (NAND) dies, etc.) assembled onto a substrate 106 (e.g., printed circuit board (PCB), interposer, etc.). In some implementations, the semiconductor device assembly 100 may be a managed NAND (mNAND) device. The logic die 102 is assembled onto the substrate 106 in a flip-chip arrangement through a direct chip attach (DCA) process. In this way, an active side of the logic die 102 at which circuitry is disposed may face the substrate 106. Contact pads 108 coupled to circuitry within the logic die 102 (e.g., through traces, lines, vias, or other connective circuitry) may be disposed at the active side of the logic die 102 and coupled with corresponding contact pads 110 disposed at an upper surface of the substrate 106 to form interconnects electrically coupling the logic die 102 and the substrate 106. The contact pads 108 and the contact pads 110 may be coupled through solder 112 (e.g., solder paste, solder balls, etc.). In some cases, solder 112 may be disposed on the contact pads 108 or the contact pads 110 and reflowed to form the interconnects. Reflowing the solder 112 may include heating the solder or the semiconductor device assembly 100 to melt the solder 112 and form solder joints electrically coupling the contact pads 108 and the contact pads 110. Underfill material 114 (e.g., capillary underfill) may be disposed between the logic die 102 and the substrate 106 to support the logic die 102 and electrically insulate the interconnects.

The stack of memory dies 104, including a DRAM die stack 118 and a NAND die stack 120, is mounted (e.g., adhered, directly bonded, etc.) on the logic die 102 and the spacer 116. The stack of memory dies 104 is stacked in a face-up arrangement such that the active side of each memory die faces away from the substrate 106. The stack of memory dies 104 is shingled such that a portion of a bottom die in the stack of memory dies 104 is exposed beyond the footprint of the top die. The active side of the memory dies may include wire bond pads (not shown) at the exposed portion to enable wires to electrically couple the stack of memory dies 104 and the substrate 106. The wire bond pads may be coupled to circuitry within the logic die (e.g., through traces, lines, vias, or other connective circuitry). A base die 122 of the DRAM die stack 118 may include wire bond pads (not shown) at the active side, the substrate 106 may include wire bond pads 124 electrically coupled to circuitry within the substrate 106 (e.g., through traces, lines, vias, or other connective circuitry), and wires 126 may electrically couple the base die 122 and the substrate 106 through the wire bond pads. The other memory dies within the DRAM die stack 118 similarly include wire bond pads at the active side to enable wires 128 to electrically couple the memory dies within the DRAM die stack 118.

The NAND die stack 120 is mounted onto the DRAM die stack 118. The NAND die stack 120 is shingled at a different side than the DRAM die stack 118. Given that the active side of each memory die faces away from the substrate 106, a bend in the wires 128 may extend above the active side of the top die 130, and film 132 may be needed to space the NAND die stack 120 from the DRAM die stack 118 and enable the wires 128 to bond to the top die 130 using film on wire (FOW) techniques. In aspects, the film 132 has a thickness that increases the overall height of the semiconductor device assembly 100. A base die 134 of the NAND die stack 120 may include wire bond pads (not shown) at the active side that are coupled to circuitry within the memory dies (e.g., through traces, lines, vias, or other connective circuitry), the substrate 106 may include wire bond pads 136 coupled to circuitry within the substrate 106 (e.g., through traces, lines, vias, or other connective circuitry), and wires 138 may electrically couple the base die 134 and the substrate 106 through the wire bond pads. The other memory dies within the NAND die stack 120 similarly include wire bond pads at the active side that are coupled with circuitry in the memory dies (e.g., through traces, lines, vias, or other connective circuitry) to enable wires 140 to electrically couple the memory dies within the NAND die stack 120.

The substrate 106 may include package-level contact pads (not shown) that provide external connectivity (e.g., via solder balls 142) to the logic die 102 or the stack of memory dies 104 (e.g., power, ground, and input/output (I/O) signals) through traces, lines, vias, and other electrical connection structures in the substrate 106 that electrically connect the package-level contact pads to the contact pads 110, the wire bond pads 124, and the wire bond pads 136. The semiconductor device assembly 100 can further include an encapsulant material 144 (e.g., mold resin compound, epoxy mold compound (EMC), or the like) that at least partially encapsulates the logic die 102, the stack of memory dies 104, and the substrate 106 to prevent electrical contact therewith and provide mechanical strength and protection to the semiconductor device assembly. In doing so, a packaged semiconductor device may be assembled.

In some cases, the semiconductor device assembly 100 may not satisfy the reliability requirements of some applications. For example, the DCA process of the logic die 102 may utilize underfill material 114 to support the logic die 102 and insulate the interconnects between the logic die 102 and the substrate 106. In some instances, the underfill material 114 may bleed out and contaminate the spacer 116, the wire bond pads 124, or the wire bond pads 136. In aspects, this contamination may cause structural failure or disrupt the electrical connection of the semiconductor device assembly 100. Moreover, the weight of the stack of memory dies 104 may cause mechanical stress in the logic die 102, which can result in failure of the semiconductor device assembly 100. In some instances, the solder 112 used to form interconnects between the semiconductor dies may be mixed with flux. During deposition or reflow of the solder, flux may contaminate portions of the semiconductor device assembly 100, and this flux residue may cause structural or electrical failure in the semiconductor device assembly 100. Further, heating during the reflow process may damage circuitry within the semiconductor dies and cause the semiconductor device assembly 100 to fail.

In some cases, the semiconductor device assembly 100 may not satisfy the spatial constraints required by some applications. For example, the stack of memory dies 104 may be electrically coupled with the substrate 106 through wires 126 and wires 138. In this way, wire bond pads 124 and wire bond pads 136 may be present beyond the footprint of the stack of memory dies 104, thereby increasing the footprint of the semiconductor device assembly 100. Further, the film 132 used to stack the memory dies in a face-up configuration may increase the height of the semiconductor device assembly 100. In aspects, the DRAM die stack 118 and the NAND die stack 120 may be implemented in a single stack of memory dies 104, which can increase the height of the semiconductor device assembly 100.

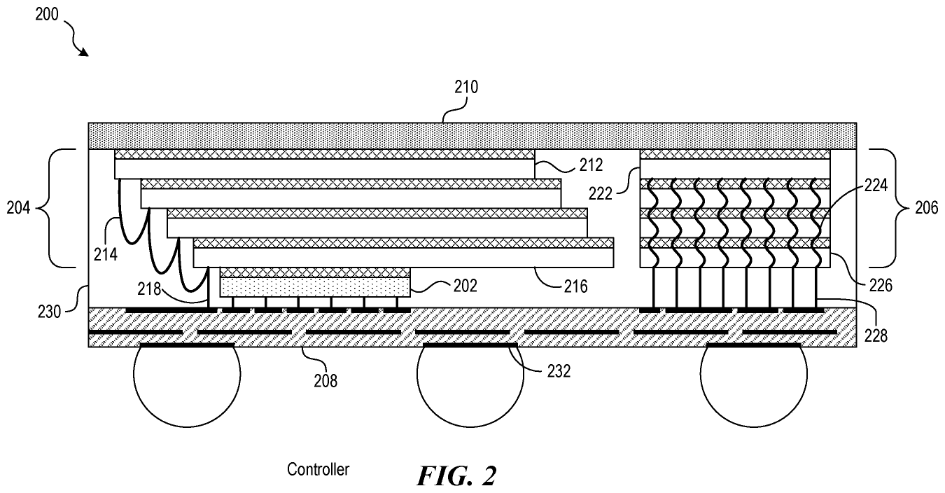

To address these drawbacks and others, various embodiments of the present technology provide semiconductor device assemblies that implement a stack of semiconductor dies. The semiconductor device assembly includes a first semiconductor die electrically coupled with a redistribution layer through first conductive structures. A stack of semiconductor dies is mounted on the first semiconductor die and electrically coupled with the redistribution layer. For example, a base die of the stack of semiconductor dies is mounted on the first semiconductor die, and second conductive structures electrically couple the base die with the redistribution layer. The semiconductor dies in the stack of semiconductor dies are electrically coupled through one or more wires. In doing so, a compact and reliable semiconductor device may be assembled. An example semiconductor device assembly is shown in FIG. 2.

FIG. 2 illustrates a semiconductor device assembly 200 that includes a first semiconductor die (e.g., logic die 202), a first stack of semiconductor dies (e.g., DRAM die stack 204), and a second stack of semiconductor dies (e.g., NAND die stack 206) electrically coupled with a redistribution layer 208. It should be noted that reference to a particular type of semiconductor die is done by way of example only, and these semiconductor dies could be replaced with a semiconductor die of any other type. For example, the first stack of semiconductor dies could include semiconductor dies of a first type, and the second stack of semiconductor dies could include semiconductor dies of a second type. The logic die may be replaced with one or more logic dies, one or more memory dies, one or more memory dies having control logic thereon, or the like. Similarly, reference to the DRAM die stack 204 or the NAND die stack 206 is done only for ease of description and should not be limited to a specific type of semiconductor die. In this way, the DRAM die stack 204 or the NAND die stack 206 can include one or more DRAM dies, NAND memory dies, NOT-OR (NOR) memory dies, magnetic random-access memory (MRAM) dies, phase change memory (PCM) dies, ferroelectric random-access memory (FeRAM) dies, static random-access memory (SRAM) dies, logic dies, or the like.

The DRAM die stack 204 may be mounted on a carrier substrate 210. For example, a DRAM die 212 (e.g., top die) of the DRAM die stack 204 may be mounted (e.g., adhered, directly bonded, etc.) on the carrier substrate 210. In aspects, the carrier substrate 210 may be a substrate that carries the DRAM die stack 204 during assembly to structurally support the semiconductor device assembly 200. In this way, the carrier substrate 210 may not be electrically coupled to circuitry within the semiconductor device assembly 200 (e.g., logic die 202, DRAM die stack 204, or NAND die stack 206). In some cases, the carrier substrate 210 may be a metal substrate to improve the thermal regulation of the semiconductor device assembly 200. In other cases, the carrier substrate 210 may be a molded substrate (e.g., formed from EMC or another mold compound) to reduce the cost of the semiconductor device assembly 200.

The DRAM die stack 204 may be mounted on the carrier substrate 210 in a face-up arrangement, such that an active side of the DRAM dies at which circuitry is disposed faces away from the carrier substrate 210 and towards the redistribution layer 208. The DRAM die stack 204 may be shingled such that a portion of each DRAM die is outside the footprint of another DRAM die mounted thereon. Wire bond pads may be disposed (not shown) at the exposed portion to enable wires 214 to electrically couple the DRAM dies of the DRAM die stack 204 at the wire bond pads. The wire bond pads may be connected to circuitry at the DRAM dies through traces, lines, vias, or other connective circuitry. In this way, electrical signals may be passed between the DRAM dies of the DRAM die stack 204 through the wires 214.

The logic die 202 may be mounted (e.g., adhered, directly attached, etc.) to the DRAM die stack 204 (e.g., on a DRAM die 216). The logic die 202 may be mounted to the DRAM die stack 204 in a face-up arrangement such that an active side of the logic die 202 faces away from the carrier substrate 210 and towards the redistribution layer 208. The logic die 202 may be shingled or may have a smaller footprint than the DRAM die 216 such that a portion of the DRAM die 216 extends beyond the footprint of the logic die 202. In aspects, the DRAM die 216 may include contacts (not shown) at the exposed portion of the DRAM die 216. The contacts may be connected to circuitry at the DRAM die 216 through traces, lines, vias, or other connective circuitry. Conductive structures 218 may extend from the contacts at the DRAM die 216 to contacts (not shown) at the redistribution layer 208 to implement interconnects that electrically couple the DRAM die stack 204 and the redistribution layer 208. The contacts at the redistribution layer 208 may be connected to circuitry at the redistribution layer 208 through traces, lines, vias, or other connective circuitry. In this way, electrical signals may be passed between the redistribution layer 208 and the DRAM die stack 204.

The logic die 202 may be similarly coupled to the redistribution layer 208. For example, contacts may be disposed at the active side of the logic die 202. The contacts may be coupled to circuitry within the logic die 202 through traces, lines, vias, or other connective circuitry. Contacts corresponding to the contacts on the logic die 202 may be disposed at the redistribution layer 208. The contacts at the redistribution layer 208 may be coupled with circuitry thereat through traces, lines, vias, or other connective circuitry. Conductive structures 220 may be formed between the contacts at the logic die 202 and the contacts at the redistribution layer 208 to implement interconnects that electrically couple the logic die 202 and the redistribution layer 208.

Similar to the DRAM die stack 204 (e.g., the top die), the NAND die stack 206 may be mounted on a carrier substrate 210. For example, a NAND die 222 of the NAND die stack 206 may be mounted (e.g., adhered, directly bonded, etc.) on the carrier substrate 210. The NAND die stack 206 may be mounted on the carrier substrate 210 in a face-up arrangement, such that an active side of the NAND dies at which circuitry is disposed faces away from the carrier substrate 210 and towards the redistribution layer 208. The NAND die stack 206 may be shingled such that a portion of the semiconductor die is outside the footprint of another semiconductor die mounted thereon. In aspects, the NAND die stack 206 may be shingled in a direction different from (e.g., a perpendicular direction) the direction in which the DRAM die stack 204 is shingled. For example, the DRAM die stack 204 is shingled in a direction coplanar with the plane shown in FIG. 2, and the NAND die stack 206 is shingled in a direction orthogonal to the plane shown in FIG. 2. Wire bond pads may be disposed (not shown) at the exposed portion to enable wires 224 to electrically couple the NAND dies of the NAND die stack 206 at the wire bond pads. The wire bond pads may be connected to circuitry at the NAND dies through traces, lines, vias, or other connective circuitry. In this way, electrical signals may be passed between the NAND dies of the NAND die stack 206 through the wires 224.

A NAND die 226 of the NAND die stack 206 may include contacts (not shown) at the exposed portion of the NAND die 226. The contacts may be connected to circuitry at the NAND die 226 through traces, lines, vias, or other connective circuitry. Conductive structures 228 may extend from the contacts at the NAND die 226 to contacts (not shown) at the redistribution layer 208 to implement interconnects that electrically couple the NAND die stack 206 and the redistribution layer 208. The contacts at the redistribution layer 208 may be connected to circuitry at the redistribution layer 208 through traces, lines, vias, or other connective circuitry. In this way, electrical signals may be passed between the redistribution layer 208 and the NAND die stack 206.

In aspects, the conductive structures 218 or the conductive structures 228 may be stud bump interconnects (e.g., gold, silver, copper, or any other conductive material) or pillar interconnects (e.g., copper pillars or other conductive pillars). In this way, wires may not be needed to electrically couple the DRAM die stack 204 or the NAND die stack 206 with the redistribution layer 208. Thus, wire bond pads that extend beyond the footprint of the DRAM die stack 204 or the NAND die stack 206 may not be needed, thereby eliminating the possibility of bond pad contamination. Instead, contacts within the footprint of the DRAM die stack 204 or the NAND die stack 206 may be disposed on the redistribution layer 208 to form vertical interconnects between the redistribution layer 208 and the DRAM die stack 204 or the NAND die stack 206. In this way, the footprint of the semiconductor device assembly 200 can be reduced. Although only illustrated on the DRAM die 216 and the NAND die 226, other DRAM dies of the DRAM die stack 204 or other NAND dies of the NAND die stack 206 may include conductive structures that electrically couple the redistribution layer 208 directly to that semiconductor die. For example, contacts may be disposed at the exposed portion of the DRAM dies or the NAND dies (e.g., similar to the wire bond pads at the DRAM die stack 204 or the NAND die stack 206), corresponding contacts may be disposed at the redistribution layer 208, and conductive structures may be formed between these contacts.

Similarly, the conductive structures 220 may be stud bump interconnects or pillar interconnects. The conductive structures 220 may not be formed through a DCA process. As a result, capillary underfill may not be needed between the logic die 202 and the redistribution layer 208 to support the logic die 202 and insulate the conductive structures 220. In this way, underfill contamination may be limited and yield may be improved. Moreover, the conductive structures 220 may not require solder. In this way, the reflow process may be eliminated, thereby limiting damage as a result of heating or flux contamination. In some cases, stud bump interconnects may be used instead of conductive pillars. For example, stud bump interconnects may be easier to implement than conductive pillars in die-die bonding. Moreover, stud bumps may not require under bump metallization (UBM), thereby reducing the design complexity of the semiconductor device assembly 200. In yet another aspect, contacts at which stud bumps are implemented may be thinner than contacts (e.g., contact pads) at which wires, solder, or conductive pillar interconnections are implemented, thereby reducing the overall height of the semiconductor device assembly 200.

A mold 230 may be disposed at least partially around the logic die 202, the DRAM die stack 204, the NAND die stack 206, the conductive structures 218, the conductive structures 220, or the conductive structures 228. The mold 230 may be formed from a mold compound, for example, a mold resin or EMC. The mold 230 may be disposed between the logic die 202, the DRAM die stack 204, the NAND die stack 206, and the redistribution layer 208. In aspects, the mold 230 may fill the area surrounding the logic die 202, the DRAM die stack 204, the NAND die stack 206, the conductive structures 218, the conductive structures 220, and the conductive structures 228 between the carrier substrate 210 and the redistribution layer 208. The mold 230 may surround the conductive structures 218, the conductive structures 220, or the conductive structures 228 such that an end of the conductive structures is exposed to the redistribution layer 208.

Layers of insulating material (e.g., dielectric material, polymer, etc.) and conductive material (coppers or any other conductive material) may be disposed at the mold 230 to implement the redistribution layer 208. As discussed above, the redistribution layer 208 may include contacts that correspond to and electrically couple with the conductive structures 218, the conductive structures 220, or the conductive structures 228. In aspects, the redistribution layer 208 may include traces, lines, vias, or other connective structures to enable electrical signals to be routed to the logic die 202, the DRAM die stack 204, or the NAND die stack 206. In aspects, the redistribution layer 208 may be used to communicate signals between a component external to the semiconductor device assembly 200 and a component internal (e.g., the logic die 202, the DRAM die stack 204, or the NAND die stack 206) to the semiconductor device assembly 200. For example, the redistribution layer 208 can include package-level contacts 232 that provide external connectivity (e.g., via solder balls) to the logic die 202, the DRAM die stack 204, or the NAND die stack 206. For example, power, ground, or I/O signals may be communicated through traces, lines, vias, and other electrical connection structures in the redistribution layer 208 that electrically connect the package-level contacts 232 to the contacts at which the conductive structures 218, the conductive structures 220, and the conductive structures 228 couple.

The redistribution layer 208 may similarly couple multiple internal components of the semiconductor device assembly 200. For example, the logic die 202 may electrically couple with the DRAM die stack 204 through the conductive structures 218, the conductive structures 220, and connective circuitry within the redistribution layer 208. Similarly, the logic die 202 may electrically couple with the NAND die stack 206 through the conductive structures 220, the conductive structures 228, and connective circuitry within the redistribution layer 208. In some cases, the redistribution layer 208 may be the only electrical coupling between the internal components. In other implementations, interconnects (e.g., wire bonds, copper pillars, etc.) may be formed between the internal circuit components to electrically couple the internal components directly with one another.

In aspects, the redistribution layer 208 may be thinner than other substrates (e.g., PCBs, interposers, etc.). For example, conductive routing layers in some substrates may be around 15 or 20 microns thick (e.g., within 1, 2, 3, or 5 microns). In contrast, the conductive routing layers (e.g., traces, lines, or other connective circuitry) within the redistribution layer 208 may be around 3 microns thick (e.g., within 1, 2, 3, or 5 microns). Similarly, in some substrates, insulating layers between the conductive routing layers may be around 20 or 30 microns thick (e.g., within 1, 2, 3, or 5 microns), while insulating layers within the redistribution layer 208 may be around 5 microns thick. When multiple conductive routing layers are implemented, the redistribution layer 208 may be substantially thinner than other substrates. For example, the redistribution layer 208 may be less than 20 microns thick, less than 30 microns thick, less than 40 microns thick, less than 50 microns thick, less than 60 microns thick, and so on.

Although illustrated in a particular configuration, it should be noted that other configurations are possible. For example, the logic die 202 may be mounted on the NAND die stack 206 instead of or in addition to the DRAM die stack 204. Moreover, a semiconductor device assembly need not include multiple stacks of semiconductor dies. For example, a semiconductor device assembly may include a single stack of NAND dies, a single stack of DRAM dies, a stack of DRAM dies and NAND dies, or a single stack of at least one other type of semiconductor dies. Further, a semiconductor device assembly can include additional stacks of semiconductor dies. For example, a semiconductor device assembly can include 3, 4, 5, 10, and so on stacks of semiconductor dies.

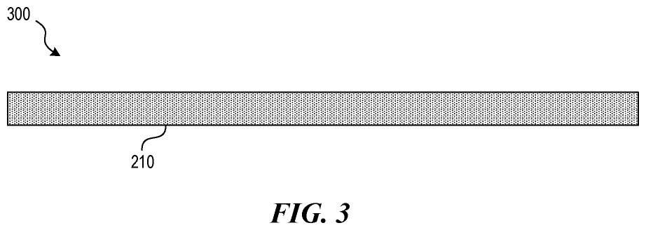

This disclosure now turns to a series of steps for fabricating semiconductor device assemblies in accordance with an embodiment of the present technology. Specifically, FIGS. 3-11 illustrate simplified schematic plan and cross-sectional views of a series of steps for fabricating semiconductor device assemblies in accordance with an embodiment of the present technology. The steps are illustrated with respect to specific embodiments for ease of description. However, the steps described with respect to FIGS. 3-11 could be performed to fabricate semiconductor device assemblies in accordance with other embodiments.

Beginning with FIG. 3 at stage 300, a carrier substrate 210 is provided. The carrier substrate 210 may be a wafer-level substrate, a panel-level substrate, or a strip-level substrate. In some cases, the carrier substrate 210 may be a metal substrate or a molded substrate. In aspects, the carrier substrate 210 does not include circuitry or contacts. For example, the carrier substrate 210 may not implement a redistribution layer that routes electrical signals to components of the semiconductor device assembly. Instead, the carrier substrate 210 may be used to provide rigidity to a semiconductor device assembly.

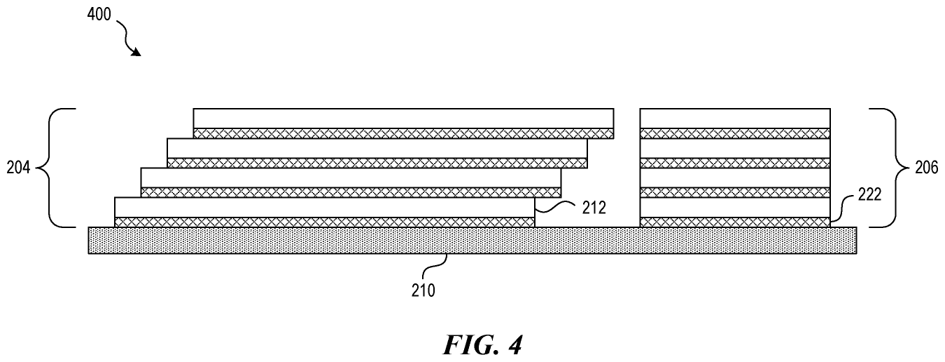

Turning to FIG. 4 at stage 400, the DRAM die stack 204 and the NAND die stack 206 are assembled onto the carrier substrate 210. In some implementations, the DRAM die stack 204 and the NAND die stack 206 may be mounted to the carrier substrate 210 through an adhesive or a dielectric material. For example, the DRAM die 212 (e.g., the base die) of the DRAM die stack 204 is mounted on the carrier substrate 210 in a face-up arrangement such that an active side of the DRAM die 212 faces away from the carrier substrate 210. Additional DRAM dies of the DRAM die stack 204 may be mounted to the DRAM die 212 in a face-up arrangement. The DRAM dies may be shingled such that a portion of the active side of a bottom DRAM die is exposed when a DRAM die is stacked on the bottom DRAM die. The NAND die stack 206 may be similarly assembled onto the carrier substrate 210. For example, a NAND die 222 (e.g., the base die) of the NAND die stack 206 may be mounted to the carrier substrate 210 in a face-up arrangement such that an active side of the NAND die 222 faces away from the carrier substrate 210. Additional NAND dies of the NAND die stack 206 may be mounted to the NAND die 222 in a face-up arrangement (e.g., a front-to-back arrangement). The NAND dies may be shingled such that a portion of the active side of a bottom NAND die is exposed when a NAND die is stacked on the bottom NAND die. In aspects, the NAND die stack 206 may be shingled along a direction different from the direction along which the DRAM die stack 204 is shingled.

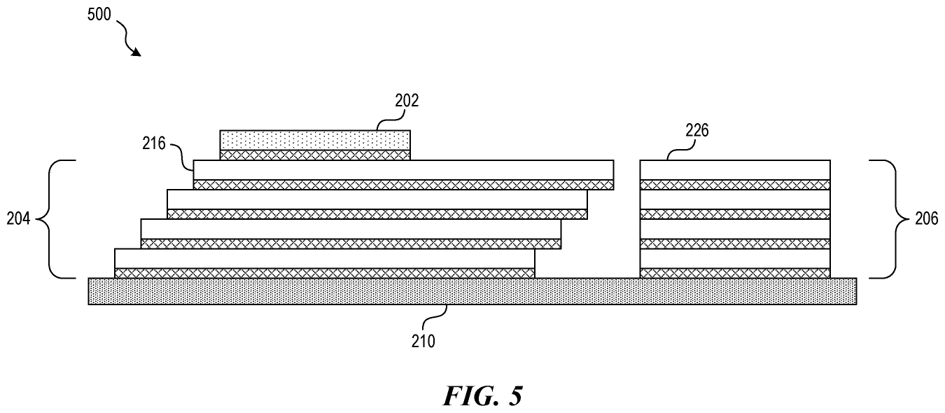

Turning to FIG. 5 at stage 500, a logic die 202 is assembled onto the DRAM die stack 204. For example, the logic die 202 may be mounted on the DRAM die stack 204 through an adhesive or a dielectric material. The logic die 202 may be assembled onto the DRAM die stack 204 in a face-up arrangement such that an active surface of the logic die 202 faces away from the carrier substrate 210 and a back side of the logic die 202 faces an active side of the DRAM die 216. The logic die 202 may be assembled onto the DRAM die 216 such that a portion of the active side of the DRAM die 216 is at least partially exposed. For example, the logic die 202 may have a smaller footprint than the DRAM die 216, or the logic die 202 may be stacked in a shingled arrangement, to expose a portion of the active side of the DRAM die 216. Although illustrated as stacked on the DRAM die 216, in some implementations, the logic die 202 may be assembled onto the NAND die stack 206 (e.g., at the NAND die 226) or any other stack of semiconductor dies.

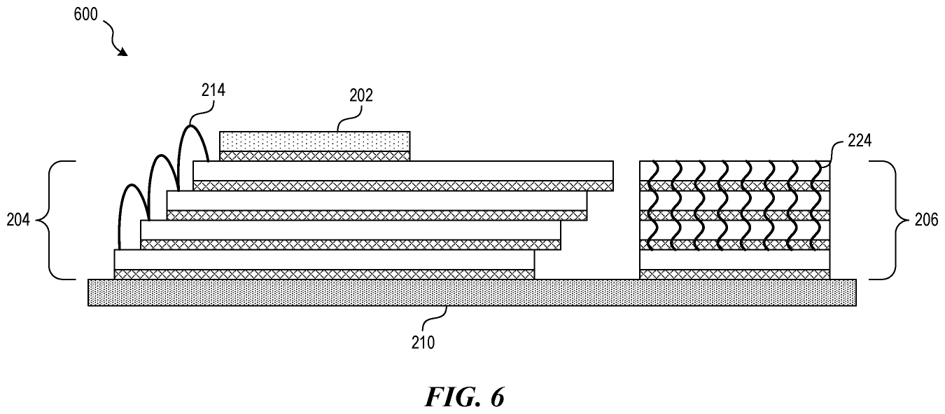

Turning next to FIG. 6 at stage 600, wire bonds are formed at the exposed portions of the DRAM die stack 204 and the NAND die stack 206. For example, the DRAM die stack 204 may include wire bond pads on an active side of the DRAM dies at the portion that is exposed by the shingled stacking of the DRAM dies. The wires 214 may be bonded to the wire bond pads to electrically couple the DRAM die stack 204. The wires 224 may similarly couple the NAND die stack 206. For example, the NAND die stack 206 may include wire bond pads on an active side of the NAND dies at the portion that is exposed by the shingled stacking of the NAND dies. The wires 224 may be bonded to the wire bond pads to electrically couple the NAND die stack 206. In some cases, the wires 214 may couple with the logic die 202 to electrically couple the DRAM die stack 204 and the logic die 202. Similarly, if the logic die 202 is stacked on the NAND die stack 206, the wires 224 may electrically couple the logic die 202 and the NAND die stack 206.

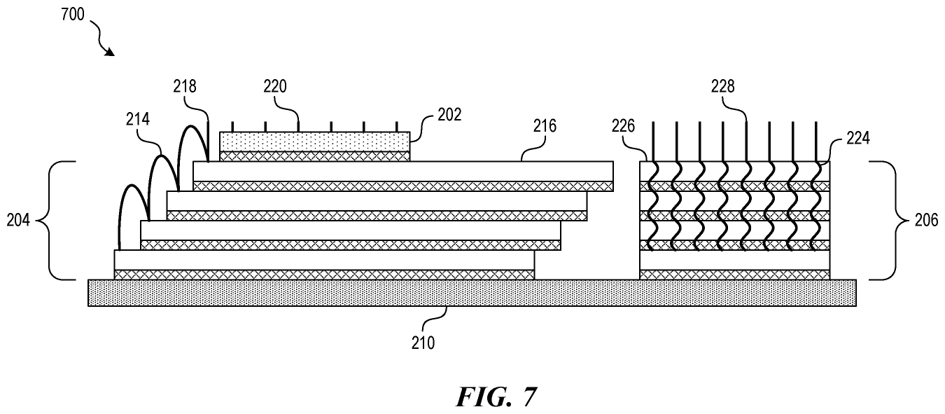

Turning next to FIG. 7 at stage 700, conductive structures 218, conductive structures 220, and conductive structures 228 are formed. In aspects, the conductive structures 218, the conductive structures 220, or the conductive structures 228 may have rigidity to enable the structures to extend from a device on which they are implemented. For instance, the conductive structures 218, the conductive structures 220, or the conductive structures 228 may be stud bumps (e.g., formed from gold wire, silver wire, copper wire, or the like), conductive pillars (e.g., copper pillars or other conductive pillars), or the like. The conductive structures 218 may be formed at contacts on an active side of the DRAM die 216 at a portion of the DRAM die 216 that is exposed beyond the footprint of the logic die 202. The conductive structures 220 and the conductive structures 228 may similarly be formed at contacts on an active side of the logic die 202 and at contacts on an active side of the NAND die 226.

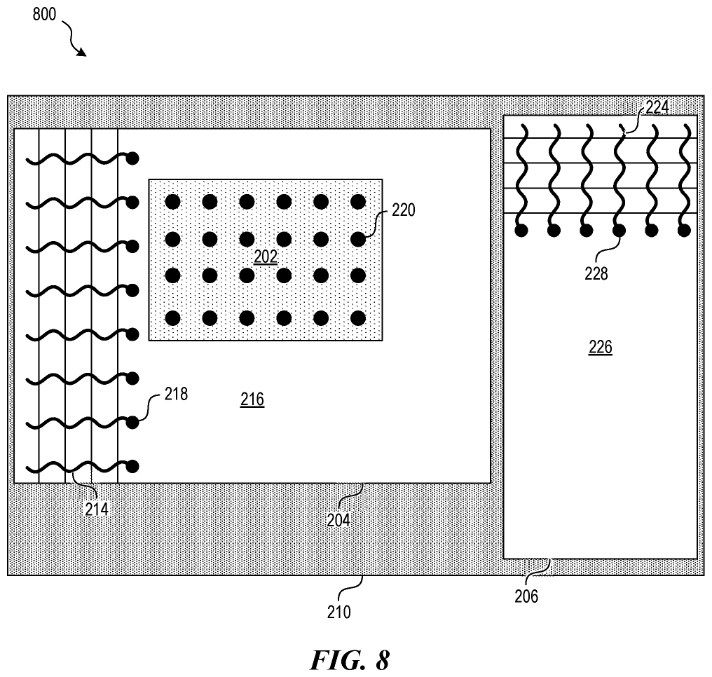

Turning next to FIG. 8 at stage 800, a plan view of the semiconductor device assembly is illustrated after the conductive structures 218, the conductive structures 220, and the conductive structures 228 are formed. As illustrated, the logic die 202 is mounted onto the DRAM die 216 of the DRAM die stack 204, which is mounted on the carrier substrate 210. The logic die 202 may be mounted on the DRAM die 216 in a shingled arrangement, or the logic die 202 may have a smaller footprint than the DRAM die 216. As a result, a portion of the active side (e.g., the side shown in FIG. 8) may be exposed outside of the footprint of the logic die 202. The conductive structures 218 may be disposed at any location along this exposed portion. Thus, although illustrated near the wires 214, the conductive structures 218 may be located at any other location along the exposed portion of the DRAM die 216. Although only illustrated at the DRAM die 216, an active side of any of the other DRAM dies within the DRAM die stack 204 may include conductive structures. For example, conductive structures may extend from a portion of the DRAM dies that is exposed due to the shingled arrangement of the DRAM die stack 204 (e.g., in a same portion of the DRAM dies at which the wires 214 are bonded). The conductive structures 220 may similarly be disposed at any location along the active side (e.g., the side shown in FIG. 8) of the logic die 202.

As illustrated, the NAND die stack 206 is also mounted on the carrier substrate 210 in a shingled arrangement. The NAND die stack 206 may be shingled in a different direction than the DRAM die stack 204. For example, as illustrated, the DRAM die stack 204 is shingled laterally and the NAND die stack 206 is shingled longitudinally. In aspects, this may enable the DRAM die stack 204 and the NAND die stack 206 to fit within a smaller footprint of the carrier substrate 210. Similar to the DRAM die 216, the conductive structures 228 may be disposed at the NAND die 226. In this example, the NAND die 226 does not have a logic die (e.g., or any other die) mounted to it. In this way, the contacts of the conductive structures 228 may be disposed at any location along the active surface of the NAND die 226, and the conductive structures 228 may be disposed at the contacts. In other cases where another semiconductor die is stacked onto the NAND die 226, however, the conductive structures 228 may be disposed at contacts that are located at any exposed portion of the NAND die 226 outside the footprint of the semiconductor die that has been mounted onto the NAND die 226. Moreover, although only illustrated at the NAND die 226, an active side of any of the other NAND dies within the NAND die stack 206 may include conductive structures. For example, the conductive structures 228 may be disposed within a same portion of the NAND dies as the wires 224.

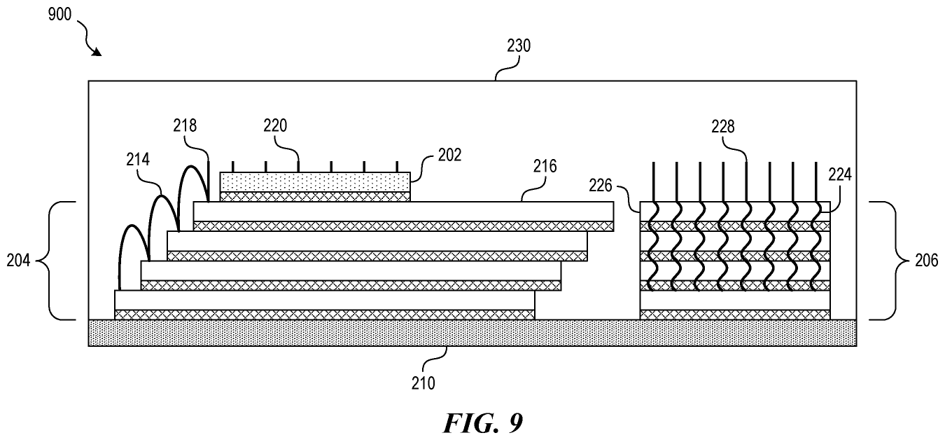

Turning next to FIG. 9 at stage 900, a mold 230 (e.g., an encapsulant) is disposed at least partially around the logic die 202, the DRAM die stack 204, the NAND die stack 206, the wires 214, the wires 224, the conductive structures 218, the conductive structures 220, or the conductive structures 228. In this way, the mold 230 may electrically insulate or structurally support the assembly. The mold 230 may be disposed on the carrier substrate 210. For example, an object mold may be placed around the assembly, or the assembly may be placed into the object mold. A mold compound may fill the object mold to form the mold 230. In aspects, the mold compound may include a mold resin compound or EMC. The mold 230 may be disposed around a distal portion (e.g., upper portion as illustrated in FIG. 9) of the conductive structures 218, the conductive structures 220, or the conductive structures 228. In doing so, electrical contact with the conductive structures may be prevented.

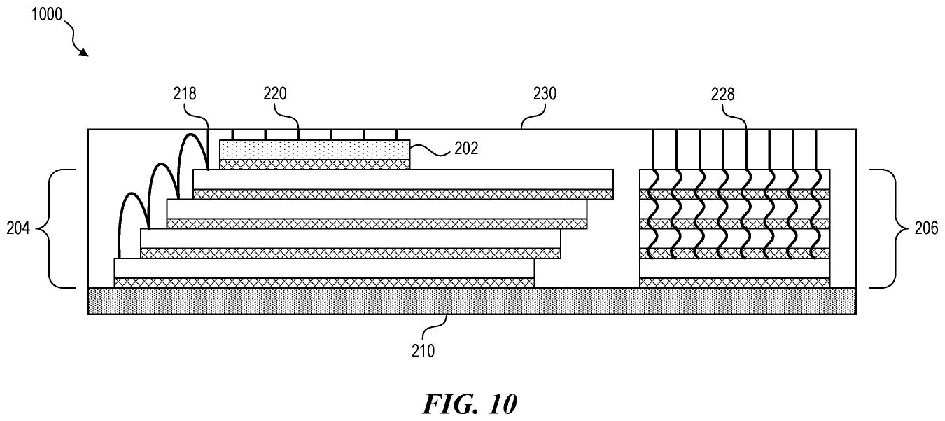

Turning next to FIG. 10 at stage 1000, material may be removed from the mold 230 at a side opposite the carrier substrate 210. The material may be removed through any appropriate technique, for example, using plasma etching, wet etching, chemical-mechanical planarization, back grinding, or the like. In aspects, the material may be removed to expose the conductive structures 218, the conductive structures 220, or the conductive structures 228. In some cases, this may include removing a distal portion of the conductive structures 218, the conductive structures 220, or the conductive structures 228. In this way, the conductive structures 218, the conductive structures 220, or the conductive structures 228 may not need to be formed to a same height in stage 700, as they may be aligned during removal of the mold material in stage 1000. In aspects, the removal of a portion of the mold 230 may create a coupling surface (e.g., an upper surface as illustrated in FIG. 10) at which the conductive structures 218, the conductive structures 220, and the conductive structures 228 are exposed. In this way, the conductive structures 218, the conductive structures 220, and the conductive structures 228 may be exposed at a distal portion opposite the DRAM die stack 204, the logic die 202, and the NAND die stack 206, respectively.

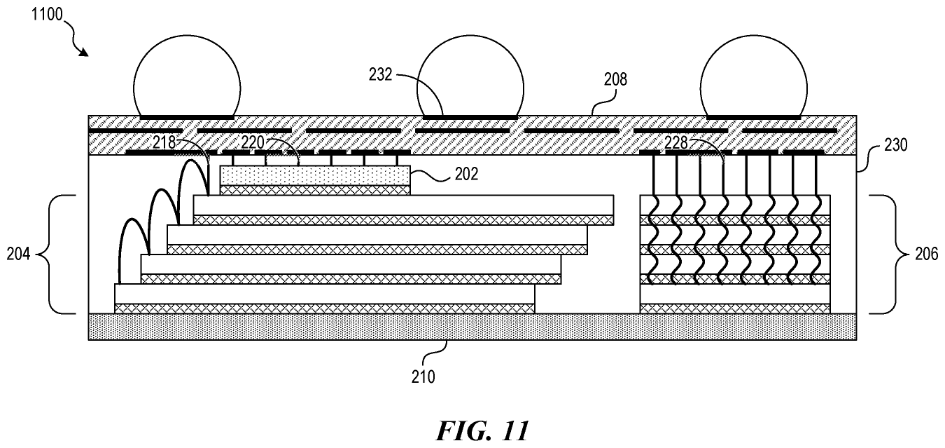

Turning next to FIG. 11 at stage 1100, a redistribution layer 208 is formed at the coupling surface (e.g., opposite the carrier substrate 210). The redistribution layer 208 may be formed from layers of conductive material (e.g., copper, gold, silver, or any other conductive material) and insulating material (e.g., dielectric material, polymer, photo-sensitive dielectric material, etc.). The conductive material and the insulating material may be disposed on the coupling surface through any appropriate method. In aspects, the redistribution layer 208 may be formed through sputtering, plating, photolithography, etching, spin coating, or any other appropriate technique. Conductive material may be used to create contacts (not shown) corresponding to the exposed portion of the conductive structures 218, the conductive structures 220, or the conductive structures 228. Insulating material may be disposed to separate the conductive material and implement separate components. For example, layers of conductive material may be disposed to implement routing layers having internal circuitry that connects to the contacts. Dielectric layers may be disposed between the routing layers to separate these layers. Package-level contacts 232 may similarly be disposed at a surface of the redistribution layer 208 that faces away from the logic die 202, the DRAM die stack 204, and the NAND die stack 206 (e.g., in a ball grid array (BGA)). The internal circuitry may couple to the package-level contacts 232 to enable electrical signals to pass from external components (e.g., connected by solder balls) to internal components coupled with the contacts at the conductive structures 218, the conductive structures 220, and the conductive structures 228. Similarly, the internal circuitry may connect multiple internal components through the contacts at the conductive structures 218, the conductive structures 220, and the conductive structures 228.

In some cases, the insulating material used to form the insulating layers of the redistribution layer 208 may have a higher dielectric constant than insulating material used in other substrates (e.g., prepreg, core materials, etc.). For example, the insulating material may include polyimide. In this way, the spacing between the routing layers may be reduced, thereby reducing the overall thickness of the redistribution layer 208. Moreover, this reduction in thickness of the redistribution layer 208 may not have adverse effects on the structural integrity of the assembly due to the rigidity provided by the mold 230 or the carrier substrate 210. As a result, the assembly may satisfy the height requirements of some electronic devices without impacting the reliability of the device.

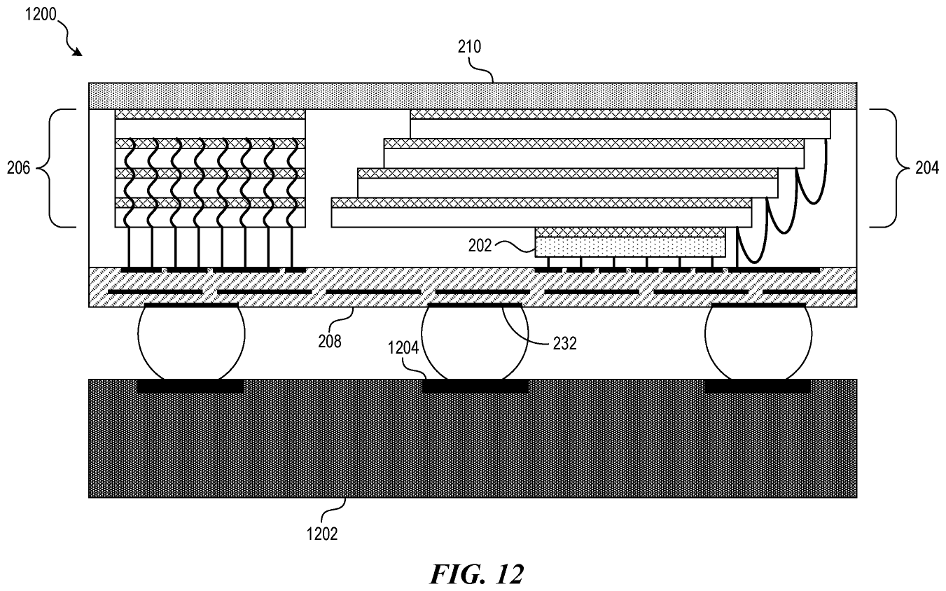

The resulting semiconductor device assembly may then be assembled onto a substrate, as illustrated in FIG. 12, to be implemented alongside other components. For example, the semiconductor device assembly illustrated in FIG. 11 may be flipped and assembled onto the substrate 1202 (e.g., a PCB, an interposer, or the like) to create the semiconductor device assembly 1200. The substrate 1202 may include contacts 1204 (e.g., contact pads) that connect to circuitry (e.g., traces, lines, vias, or other connective circuitry) within the substrate 1202 and correspond to the package-level contacts 232. Solder balls or other connective circuitry may form interconnects between the contacts 1204 and the package-level contacts 232. In this way, the substrate 1202 may provide external connectivity (e.g., power, ground, and I/O signals) to the logic die 202, the DRAM die stack 204, or the NAND die stack 206 through traces, lines, vias, and other connective structures in the redistribution layer 208. The substrate 1202 may further include additional components coupled therewith. In this way, the logic die 202, the DRAM die stack 204, or the NAND die stack 206 may be electrically coupled to other components through the circuitry within the substrate 1202 and the circuitry within the redistribution layer 208.

In some cases, the carrier substrate 210 may be left on the assembly. For example, the carrier substrate 210 may provide additional rigidity to the assembly, thus improving reliability. In some implementations, the carrier substrate 210 may include a metal or other conductive material. In this way, the carrier substrate 210 may dissipate heat from the semiconductor device assembly and improve its thermal properties. In other implementations, the carrier substrate 210 may include a mold material, for example, a mold resin compound or EMC. In this way, the overall cost of the semiconductor device assembly may be reduced. In yet another aspect, at least a portion of the carrier substrate 210 may be removed. For example, a portion or the entirety of the carrier substrate 210 may be removed through plasma etching, wet etching, chemical-mechanical planarization, back grinding, delamination, or the like. As a result, the height of the semiconductor device assembly may be reduced.

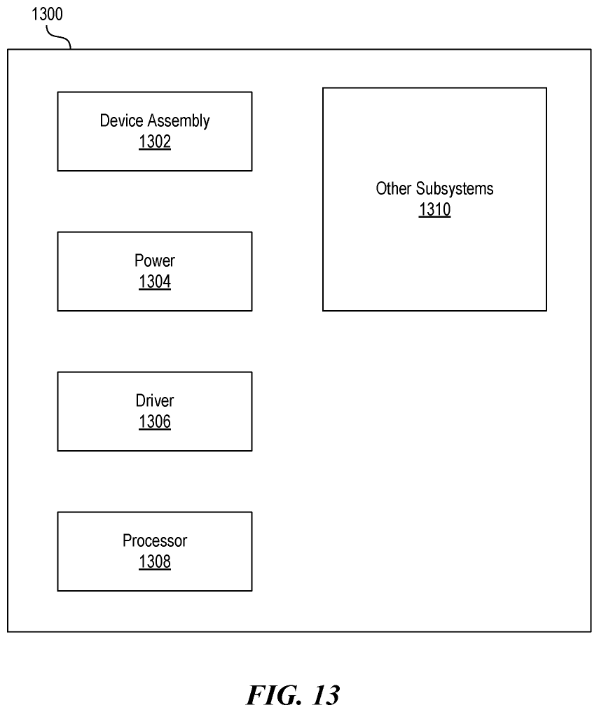

Any one of the semiconductor devices and semiconductor device assemblies described above with reference to FIGS. 1-12 can be incorporated into any of a myriad of larger and/or more complex systems, a representative example of which is system 1300 shown schematically in FIG. 13. The system 1300 can include a semiconductor device assembly 1302 (e.g., or a discrete semiconductor device), a power source 1304, a driver 1306, a processor 1308, and/or other subsystems or components 1310. The semiconductor device assembly 1302 can include features generally similar to those of the semiconductor device assemblies described above with reference to FIGS. 1-12. The resulting system 1300 can perform any of a wide variety of functions, such as memory storage, data processing, and/or other suitable functions. Accordingly, representative systems 1300 can include, without limitation, hand-held devices (e.g., mobile phones, tablets, digital readers, and digital audio players), computers, vehicles, appliances, and other products. Components of the system 1300 may be housed in a single unit or distributed over multiple, interconnected units (e.g., through a communications network). The components of the system 1300 can also include remote devices and any of a wide variety of computer-readable media.

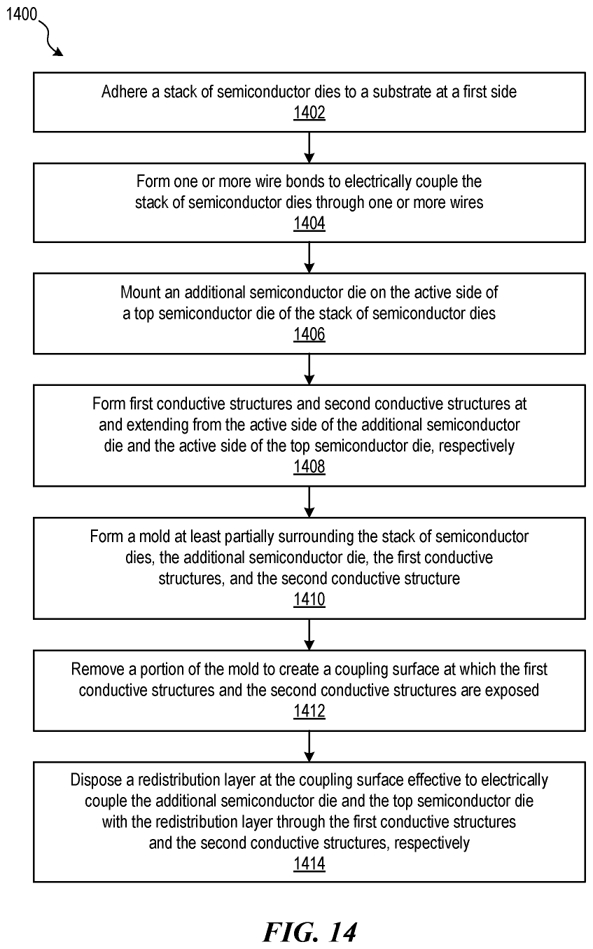

FIG. 14 illustrates an example method 1400 for fabricating a semiconductor device assembly in accordance with an embodiment of the present technology. The method 1400 may, for illustrative purposes, be described with respect to features, components, or elements of FIGS. 1-13. However, these descriptions are made by way of example only and do not limit the method 1400 from being implemented with other like features. Although illustrated in a particular configuration, one or more operations of the method 1400 may be omitted, repeated, or reorganized. Additionally, the method 1400 may include other operations not illustrated in FIG. 14, for example, operations detailed in one or more other methods described herein.

At 1402, a stack of semiconductor dies (e.g., DRAM die stack 204, NAND die stack 206, etc.) is adhered to the substrate (e.g., carrier substrate 210) at a first side. In aspects, the substrate may be a carrier substrate that does not include routing circuitry. In this way, the stack of semiconductor dies may not be electrically coupled to the substrate. Instead, the substrate may provide rigidity to the assembly during or after processing. The stack of semiconductor dies may be shingled such that an active side of each semiconductor die is exposed outside of the footprint of another semiconductor die of the stack of semiconductor dies. The stack of semiconductor dies may be stacked in a front-to-back arrangement such that an active side of each semiconductor die faces away from the substrate and toward the back side of another semiconductor die. In aspects, the stack of semiconductor dies includes a top semiconductor die (e.g., DRAM die 216, NAND die 226, etc.) having an active side and a back side opposite the active side.

At 1404, one or more wire bonds are formed to electrically couple the stack of semiconductor dies through one or more wires (e.g., wires 214, wires 224, etc.). For example, a wire bond pad may be disposed at an active side of the semiconductor dies at the exposed portion. Wires may form interconnections between the semiconductor dies of the stack of semiconductor dies. At 1406, an additional semiconductor die (e.g., logic die 202) may be mounted on the active side of the top semiconductor die of the stack of semiconductor dies. The additional semiconductor die may include an active side and a back side opposite the active side. In aspects, the additional semiconductor die may be mounted to the top semiconductor die such that the active side faces away from the substrate.

At 1408, first conductive structures (e.g., conductive structures 220) and second conductive structures (e.g., conductive structures 218, conductive structures 228, etc.) are formed at and extending from the active side of the additional semiconductor die and the active side of the top semiconductor die, respectively. In aspects, the conductive structures may be conductive pillars or stud bumps. At 1410, a mold 230 is formed at least partially surrounding the stack of semiconductor dies, the additional semiconductor die, the first conductive structures, and the second conductive structures. At 1412, a portion of the mold is removed to create a coupling surface at which the first conductive structures and the second conductive structures are exposed.

At 1414, a redistribution layer (e.g., redistribution layer 208) is disposed at the coupling surface to electrically couple the additional semiconductor die and the top semiconductor die with the redistribution layer through the first conductive structures and the second conductive structures. For example, contacts may be disposed at a surface of the redistribution layer that faces the first conductive structures and the second conductive structures. The contacts may correspond to the first conductive structures and the second conductive structures such that the first conductive structures and the second conductive structures electrically couple with the redistribution layer through the contacts. In some implementations, an additional stack of semiconductor dies (e.g., DRAM die stack 204, NAND die stack 206, etc.) may be adhered to the substrate at the first side. The additional stack of semiconductor dies may include an additional top semiconductor die (e.g., DRAM die 216, NAND die 226, etc.) having an active side and a back side opposite the active side. Third conductive structures (e.g., conductive structures 218, conductive structures 228, etc.) may be formed at and extending from the active side of the additional top semiconductor die. In this way, forming the redistribution layer at the coupling surface may be effective to electrically couple the additional top semiconductor die with the redistribution layer through the third conductive structures. In some cases, a portion of the substrate may be removed to reduce the size of the semiconductor device assembly. In general, however, performing the method 1400 may fabricate a compact and reliable semiconductor device assembly.

Specific details of several embodiments of semiconductor devices, and associated systems and methods, are described above. Unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional interface (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a redistribution layer having a first side and a second side opposite the first side;
a first semiconductor die electrically coupled with the redistribution layer at the first side through first conductive structures; and
a stack of semiconductor dies mounted on the first semiconductor die and electrically coupled with the redistribution layer, the stack of semiconductor dies including:
a base semiconductor die mounted on the first semiconductor die and electrically coupled with the redistribution layer at the first side through second conductive structures; and
one or more wires electrically coupling respective semiconductor dies of the stack of semiconductor dies.

2. The semiconductor device assembly of claim 1, wherein:
each semiconductor die of the stack of semiconductor dies includes an active side and a back side opposite the active side; and
the stack of semiconductor dies is mounted on the first semiconductor die such that the active side of each semiconductor die of the stack of semiconductor dies faces the redistribution layer.

3. The semiconductor device assembly of claim 1, wherein the first conductive structures or the second conductive structures include stud bump interconnects or pillar interconnects.

4. The semiconductor device assembly of claim 1, wherein the redistribution layer includes polyimide.

5. The semiconductor device assembly of claim 1, further comprising a mold disposed around the first semiconductor die, the stack of semiconductor dies, the first conductive structures, and the second conductive structures, wherein the redistribution layer is in contact with the mold.

6. The semiconductor device assembly of claim 1, further comprising a substrate adhered directly to a topmost semiconductor die in the stack of semiconductor dies.

7. The semiconductor device assembly of claim 1, wherein:
the first semiconductor die comprises a logic die; and
the stack of semiconductor dies includes a stack of memory dies.

8. A method for fabricating a semiconductor device assembly, comprising:
providing a substrate having a first side and a second side opposite the first side;
adhering a stack of semiconductor dies to the substrate at the first side,
wherein the stack of semiconductor dies includes a top semiconductor die having an active side and a back side opposite the active side;
forming one or more wire bonds to electrically couple the stack of semiconductor dies through one or more wires;
mounting an additional semiconductor die on the active side of the top semiconductor die of the stack of semiconductor dies,
wherein the additional semiconductor die includes an active side and a back side opposite the active side;
forming first conductive structures at and extending from the active side of the additional semiconductor die;
forming second conductive structures at and extending from the active side of the top semiconductor die;
forming a mold at least partially surrounding the stack of semiconductor dies, the additional semiconductor die, the first conductive structures, and the second conductive structures;
removing a portion of the mold to create a coupling surface at which the first conductive structures and the second conductive structures are exposed; and
disposing a redistribution layer at the coupling surface to electrically couple the additional semiconductor die and the top semiconductor die with the redistribution layer through the first conductive structures and the second conductive structures, respectively.

9. The method of claim 8, further comprising removing at least a portion of the substrate.

10. The method of claim 8, wherein:
forming the first conductive structures includes forming stud bumps or conductive pillars at the active side of the additional semiconductor die; or
forming the second conductive structures includes forming stud bumps or conductive pillars at the active side of the top semiconductor die.

11. The method of claim 8, further comprising:
adhering an additional stack of semiconductor dies to the substrate at the first side,
wherein the additional stack of semiconductor dies includes an additional top semiconductor die having an active side and a back side opposite the active side; and
forming third conductive structures at and extending from the active side of the additional top semiconductor die,
wherein the third conductive structures are exposed at the coupling surface, and
wherein disposing the redistribution layer at the coupling surface is effective to electrically couple the additional top semiconductor die with the redistribution layer through the third conductive structures.

12. The method of claim 8, further comprising disposing contacts at a surface of the redistribution layer that faces the first conductive structures and the second conductive structures, the contacts electrically coupled with the first conductive structures and the second conductive structures.

13. The method of claim 8, wherein the stack of semiconductor dies is not electrically coupled to the substrate.

14. A semiconductor device assembly, comprising:
a redistribution layer having a first side and a second side opposite the first side;
a first semiconductor die electrically coupled with the redistribution layer at the first side through first interconnects;
a stack of semiconductor dies mounted on the first semiconductor die such that an active side of each semiconductor die of the stack of semiconductor dies faces the redistribution layer, the stack of semiconductor dies including:
a base semiconductor die mounted on the first semiconductor die and electrically coupled with the redistribution layer at the first side through second interconnects; and
one or more wires electrically coupling respective semiconductor dies of the stack of semiconductor dies; and
an additional stack of semiconductor dies mounted on and electrically coupled to the redistribution layer at the first side through third interconnects such that an active side of each semiconductor die of the additional stack of semiconductor dies faces the redistribution layer, the additional stack of semiconductor dies including one or more additional wires electrically coupling respective semiconductor dies of the additional stack of semiconductor dies.

15. The semiconductor device assembly of claim 14, wherein:
the stack of semiconductor dies comprises memory dies of a first type; and
the additional stack of semiconductor dies comprises memory dies of a second type different from the first type.

16. The semiconductor device assembly of claim 14, wherein:
the stack of semiconductor dies comprises one of: dynamic random-access memory (DRAM) dies and NOT-AND (NAND) dies; and
the additional stack of semiconductor dies comprises another of: DRAM dies and NAND dies.

17. The semiconductor device assembly of claim 14, wherein the first interconnects, the second interconnects, or the third interconnects comprise stud bump interconnects or conductive pillar interconnects.

18. The semiconductor device assembly of claim 14, wherein:
the stack of semiconductor dies is shingled along a first direction; and
the additional stack of semiconductor dies is shingled along a second direction different from the first direction.

19. The semiconductor device assembly of claim 14, further comprising a mold disposed around the first semiconductor die, the stack of semiconductor dies, the additional stack of semiconductor dies, the first interconnects, the second interconnects, and the third interconnects, wherein the redistribution layer is in contact with the mold.

20. The semiconductor device assembly of claim 14, further comprising a substrate adhered directly to a topmost semiconductor die in the stack of semiconductor dies and an additional topmost semiconductor die in the additional stack of semiconductor dies.
